(19) United States
(12) Patent Application Publication
(10) Pub. No.: US 2018/0275519 A1
(43) Pub. Date: Sep. 27, 2018

(54) Pattern Formation Method

(71) Applicant: TOSHIBA MEMORY CORPORATION, Tokyo (JP)

(72) Inventors: Ayako KAWANISHI, Yokkaichi Mie (JP); Takehiro Kondoh, Yokkaichi Mie (JP); Yusuke Kasahara, Yokohama (JP)

(73) Assignee: TOSHIBA MEMORY CORPORATION, Tokyo (JP)

(21) Appl. No.: 15/696,130

(22) Filed: Sep. 5, 2017

(30) Foreign Application Priority Data
Mar. 22, 2017 (JP) 2017-056499

(51) Int. Cl. G03F 7/20; H01L 21/033

(52) U.S. Cl. CPC G03F 7/2022; H01L 21/0332; G03F 7/26; H01L 21/0337; H01L 21/0338

(57) ABSTRACT

A pattern formation method includes forming a first pattern in a first film in a first region and forming a second pattern in the first film in a second region by using an optical lithography technology. The pattern formation method also includes forming a third pattern corresponding to the first pattern in a second film below the first film in the first region by using a self-organization lithography technology. The pattern formation method also includes transferring the third pattern to a third film below the first film and the second film in the first region and transferring the second pattern to the third film in the second region.

### CROSS-REFERENCE TO RELATED APPLICATION

This application claims the benefit of and priority to Japanese Patent Application No. 2017-056499, filed Mar. 22, 2017, the entire contents of which are incorporated herein by reference.

### FIELD

Embodiments described herein relate generally to a pattern formation method.

### BACKGROUND

By using a self-organization lithography technology, predetermined patterns are formed on a substrate. In this case, it is desired to efficiently form the patterns.

### DESCRIPTION OF THE DRAWINGS

FIG. 1A, FIG. 1B and FIG. 1C are process sectional views illustrating a pattern formation method according to some embodiments.

FIG. 2A, FIG. 2B and FIG. 2C are process sectional views illustrating a pattern formation method according to some embodiments.

FIG. 3A, FIG. 3B and FIG. 3C are process sectional views illustrating a pattern formation method according to some embodiments.

FIG. 4A and FIG. 4B are process sectional views illustrating a pattern formation method according to some embodiments.

FIG. 5A and FIG. 5B are process sectional views illustrating a pattern formation method according to some embodiments.

FIG. 6A, FIG. 6B and FIG. 6C are process sectional views illustrating a pattern formation method according to a modification example of some embodiments.

FIG. 7A, FIG. 7B and FIG. 7C are process sectional views illustrating a pattern formation method according to a modification example of some embodiments.

FIG. 8A, FIG. 8B and FIG. 8C are process sectional views illustrating a pattern formation method according to a modification example of some embodiments.

FIG. 9A, FIG. 9B and FIG. 9C are process sectional views illustrating a pattern formation method according to a modification example of some embodiments.

FIG. 10A and FIG. 10B are process sectional views illustrating a pattern formation method according to a modification example of some embodiments.

### DETAILED DESCRIPTION

An example embodiment provides a pattern formation method capable of efficiently forming patterns by using a self-organization lithography technology.

In general, according to some embodiments, a pattern formation method may include forming a first pattern in a first film in a first region and forming a second pattern in the first film in a second region by using an optical lithography technology. The pattern formation method may include forming a third pattern corresponding to the first pattern in a second film below the first film in the first region by using a self-organization lithography technology. The pattern formation method may include transferring the third pattern to a third film below the first film and the second film in the first region and transferring the second pattern to the third film in the second region.

In the following, with reference to the drawings, a pattern formation method according to example embodiments will be described in detail. It is noted that the present disclosure is not limited to these embodiments.

A pattern formation method according to some embodiments will be described. The pattern formation method may include forming predetermined patterns on a substrate. In some embodiments, in a lithography technology for forming the predetermined patterns on the substrate, the patterns may be miniaturized.

As a lithography technology of a manufacturing process of a semiconductor element, a double patterning technology by ArF immersion exposure, EUV lithography, nanoimprint and the like can be used; however, some lithography technology may cause an increase in cost, a reduction of throughput and the like with the miniaturization of patterns.

In such a situation, a self-organization (DSA: Directed Self-Assembly) material can be applied to the lithography technology. The self-organization material (DSA material) can be organized by a spontaneous behavior for energy stabilization, so that it can be applied to form a pattern with high dimensional accuracy.

For example, in a technology using microphase separation of a polymer block copolymer, it is possible to form various shapes of periodic structures of several nm (nanometers) to several hundreds of nm by a coating and annealing process. A shape may be changed to a spherical shape (or a sphere), a columnar shape (or a cylinder), a layered shape (or a lamella) and the like by a composition ratio of blocks of a polymer block copolymer and a size may be changed by a molecular weight, so that it is possible to form various dimensions of dot patterns, holes, pillar patterns, line patterns and the like.

In order to form desired patterns in a wide range by using the DSA material, it is possible to provide a guide for controlling a generation position of a polymer phase formed by self-organization. The guide can be a physical guide (e.g., grapho-epitaxy) having an uneven structure and forming a microphase separation pattern in a recess portion, or a chemical guide (e.g., chemical-epitaxy) formed at a lower layer of the DSA material and controlling a formation position of a microphase separation pattern on the basis of a difference of surface energy thereof.

For example, a resist film may be formed on a processed film, resist may be exposed to form a hole pattern serving as a physical guide, and a block copolymer (BCP) may be embedded in the physical guide and may be heated. Then, the BCP may be phase-separated (microphase-separated) into a first polymer portion formed along a sidewall of a guide pattern, and a second polymer portion formed at a center of the guide pattern. Thereafter, the second polymer portion may be selectively removed and the first polymer portion may be allowed to remain, a pattern (for example, the hole pattern) having a dimension smaller than that of the guide pattern can be processed and transferred to a base film. This is called a DSA hole shrink process.

That is, when the guide pattern is formed with a dimension near a resolution limit in optical lithography, since a pattern (for example, the hole pattern) having a dimension smaller than the resolution limit can be formed in the base film, a pattern can be miniaturized to be smaller than the resolution limit of the optical lithography.

However, in the DSA hole shrink process, since a hole diameter is determined based on a molecular weight of the BCP, it may be difficult to simultaneously form patterns (for example, a cell portion, a peripheral circuit and the like) with dimensions different from one another. Therefore, when a lithography process is provided to each pattern, it is possible that the number of processes will easily increase and cost will increase.

In this regard, in some embodiments, pattern formation using the self-organization lithography technology may be performed and a part of the physical guide may be used for the pattern formation as is, resulting in a reduction of the number of processes required for forming patterns with dimensions different from one another.

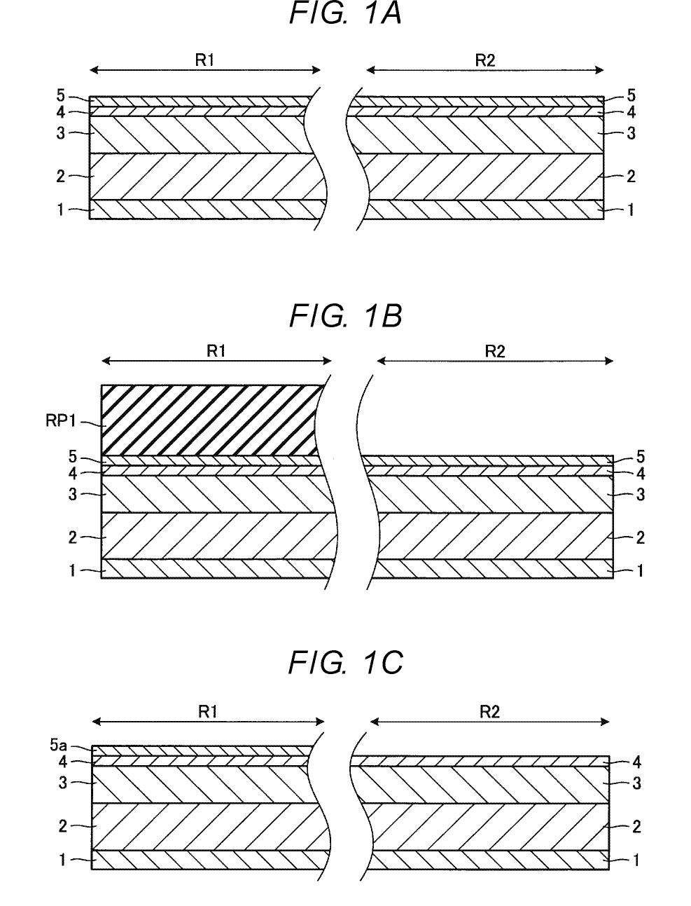

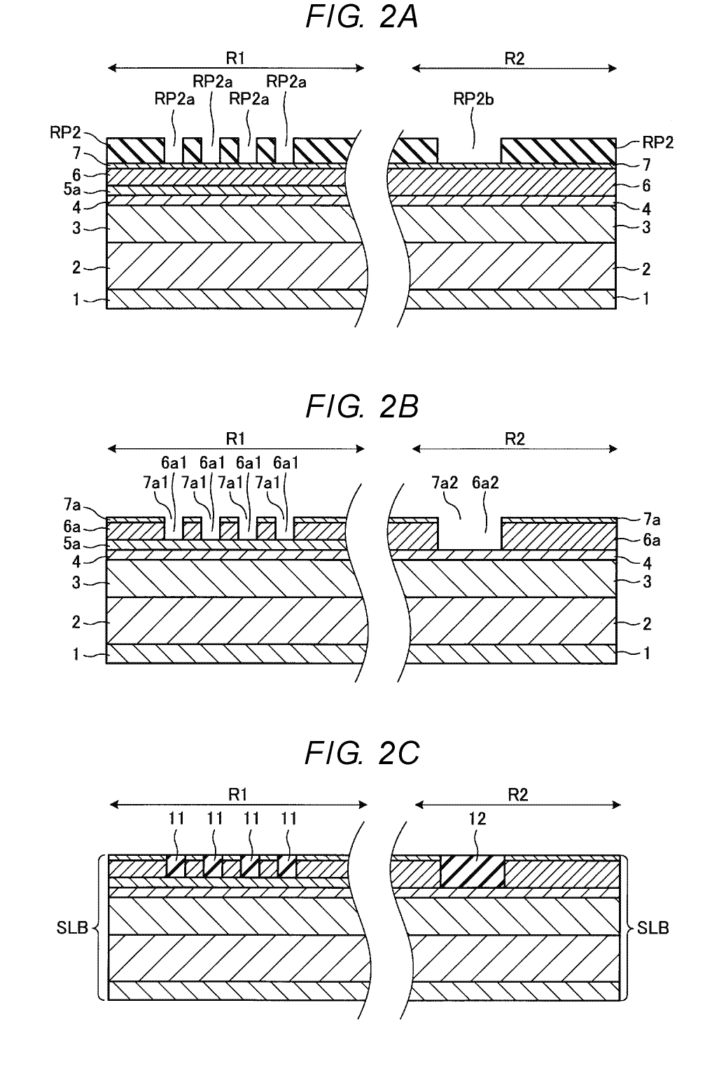

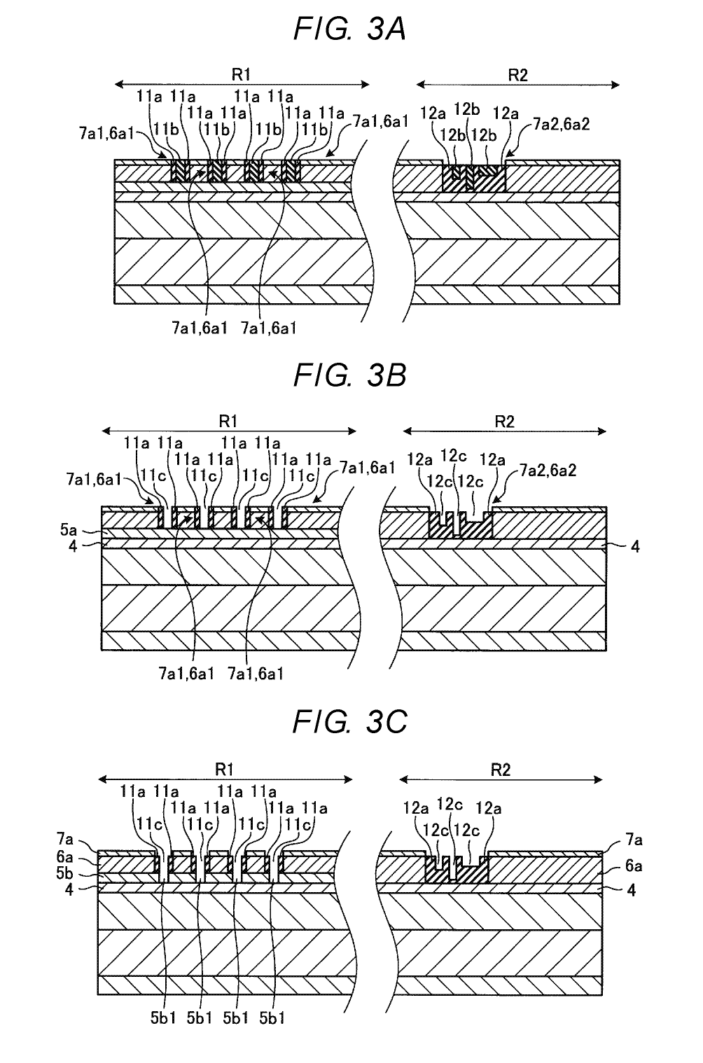

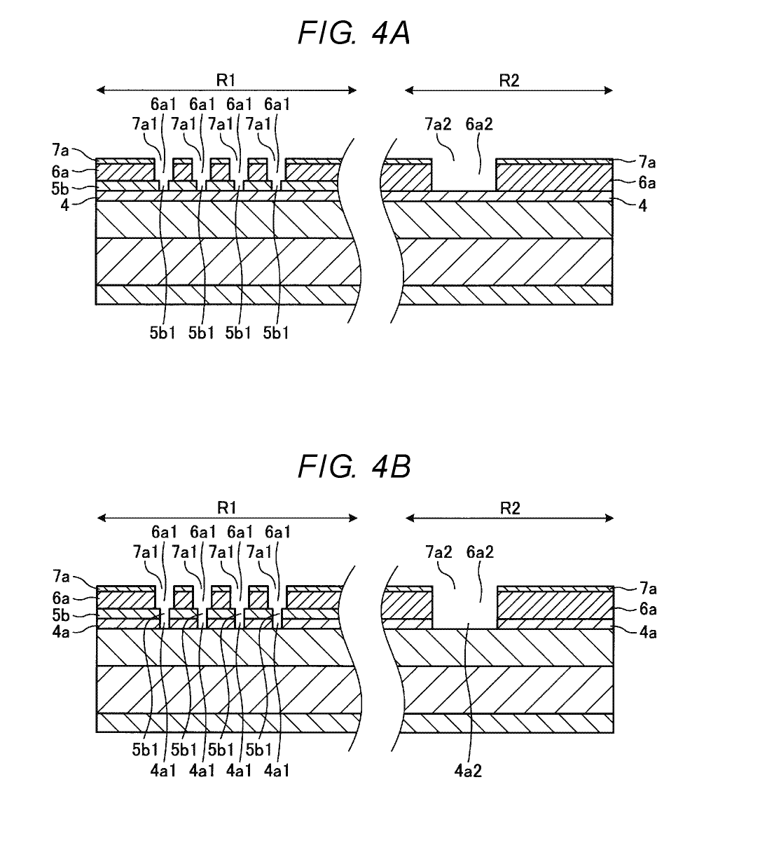

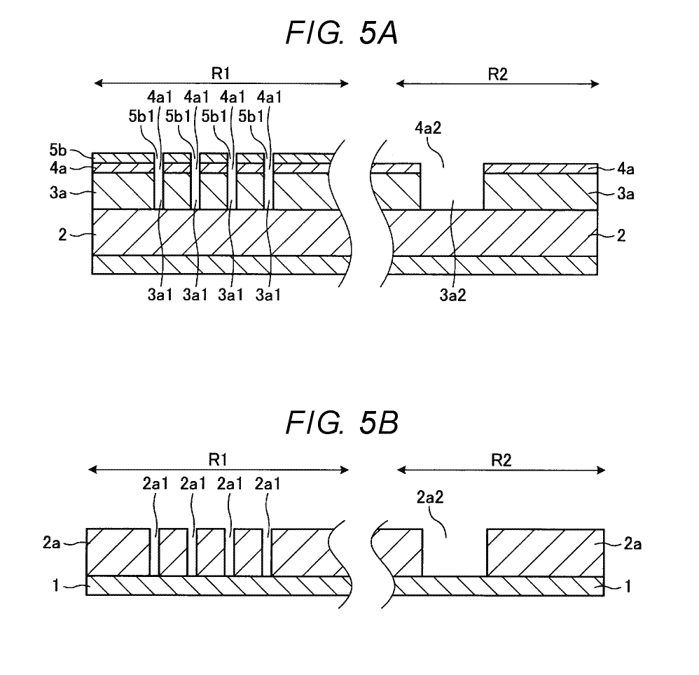

In some embodiments, as illustrated in FIG. 1A to FIG. 5B, predetermined patterns are formed on a substrate. FIG. 1A to FIG. 1C, FIG. 2A to FIG. 2C, FIG. 3A to FIG. 3C, FIG. 4A and FIG. 4B, and FIG. 5A and FIG. 5B are process sectional views illustrating a pattern formation method, respectively.

In the process illustrated in FIG. 1A, a substrate 1 is prepared. The substrate 1, for example, can be formed with a material in which a semiconductor such as silicon is a main component. The substrate 1 may have a region R1 and a region R2. The region R1 and the region R2 may be regions where patterns with different dimensions are to be formed. The region R1 may be a region where patterns with a dimension smaller than that of the region R2 are to be formed, and for example, maybe a cell region where a fine pattern such as memory cells are disposed. The region R2 may be a region where patterns with a dimension larger than that of the region R1 are to be formed, and for example, may be a peripheral region where a peripheral circuit for the cell region is disposed. In the region R1 and the region R2, a processed film 2, a hard mask 3, a hard mask 4, and a hard mask 5 may be sequentially deposited on the substrate 1.

For example, the processed film 2 can be formed with a material, in which silicon oxide is a main component, by a CVD (Chemical Vapor Deposition) method, a spin coating method and the like. When the processed film 2 is formed by the spin coating method, the processed film 2 can also be called a SOG (Spin On Glass) film. The processed film 2 can be formed with a thickness of 150 nm. The hard mask 3 can be formed with a material, in which carbon is a main component, by the CVD method, the spin coating method and the like. When the hard mask 3 is formed by the spin coating method, the hard mask 3 can also be called a SOC (Spin On Carbon) film. The hard mask 3 can be formed with a thickness of 100 nm. The hard mask 4 can be formed with a material, in which silicon oxide is a main component, by the CVD method and the like. The hard mask 4 can be formed with a thickness of 15 nm. The hard mask 5 can be formed with a material, in which silicon nitride is a main component, by the CVD method and the like. The hard mask 5 can be formed with a thickness of 15 nm.

In the process illustrated in FIG. 1B, a resist pattern RP1 selectively covering the part of the region R1 in the hard mask 5 may be formed.

For example, a resist material may be coated on the hard mask 5 by the spin coating method and the like. The resist material can be coated to be a thickness of 1.5 μm. The resist material may be exposed and developed by MUV (Middle Ultra Violet) light, so that a resist film selectively remains on the region R1 and is selectively removed from the region R1. In this way, the resist pattern RP1 selectively covering the part of the region R1 in the hard mask 5 may be formed.

In the process illustrated in FIG. 1C, a hard mask 5a for selectively covering the part of the region R1 in the hard mask 4 may be formed.

By the RIE, the hard mask 5 may be etched using the resist pattern RP1 as a mask. In this way, the part of the region R1 in the hard mask 5 may be selectively removed, so that the hard mask 5a selectively covering the region R1 is formed.

In the process illustrated in FIG. 2A, on the hard mask 5a and the hard mask 4, a hard mask 6, an antireflection film 7, and a resist pattern RP2 may be formed.

For example, the hard mask 6 can be formed with a material, in which carbon is a main component, by the CVD method, the spin coating method and the like. When the hard mask 6 is formed by the spin coating method, the hard mask 6 can also be called a SOC (Spin On Carbon) film. The hard mask 6 can be formed with a thickness of 100 nm. The antireflection film 7 can be formed with a material, in which silicon oxide is amain component, by the CVD method, the spin coating method and the like. When the antireflection film 7 is formed by the spin coating method, the antireflection film 7 can also be called a SOG (Spin On Glass) film. The antireflection film 7 can be formed with a thickness of 30 nm.

A resist material may be coated on the antireflection film 7 by the spin coating method and the like. The resist material can be coated to be a thickness of 120 nm. The resist material may be exposed and developed by ArF immersion excimer laser and the like, thereby forming a resist pattern RP2 having a hole pattern RP2a in the region R1 and having a hole pattern RP2b in the region R2. A maximum width of the hole pattern RP2a may be smaller than that of the hole pattern RP2b. A diameter of the hole pattern RP2a, for example, is 70 nm and a diameter of the hole pattern RP2b, for example, is 200 nm.

In this case, the hard mask 5a may exist between a bottom surface (e.g., a surface of the antireflection film 7 exposed through the hole pattern RP2a) of the hole pattern RP2a and the hard mask 4, but it is possible that the hard mask 5a does not exist between a bottom surface (e.g., a surface of the antireflection film 7 exposed through the hole pattern RP2b) of the hole pattern RP2b and the hard mask 4.

In the process illustrated in FIG. 2B, the hole patterns RP2a and RP2b in the resist pattern RP2 may be transferred to an antireflection film 7a and a hard mask 6a.

For example, by the RIE method and the like, the antireflection film 7 may be etched using the resist pattern RP2 as a mask. In this way, the hole patterns RP2a and RP2b in the resist pattern RP2 may be transferred to the antireflection film 7a. That is, in the region R1, a hole pattern 7a1 corresponding to the hole pattern RP2a may be formed in the antireflection film 7a, and in the region R2, a hole pattern 7a2 corresponding to the hole pattern RP2b may be formed in the antireflection film 7a.

Then, by the RIE method and the like, the hard mask 6a may be etched using the antireflection film 7a as a mask. In this way, the hole patterns 7a1 and 7a2 in the antireflection film 7a may be transferred to the hard mask 6a. That is, in the region R1, a hole pattern 6a1 corresponding to the hole pattern 7a1 may be formed in the hard mask 6a, and in the region R2, a hole pattern 6a2 corresponding to the hole pattern 7a2 may be formed in the hard mask 6a. The formed recess patterns (e.g., the hole patterns 7a1 and 6a1 and the hole patterns 7a2 and 6a2) may serve as physical guides of a self-organization pattern of a subsequent process.

In the process illustrated in FIG. 2C, in the physical guides (e.g., the hole patterns 7a1 and 6a1) of the region R1 and the physical guides (the hole patterns 7a2 and 6a2) of the region R2, self-organization materials may be respectively embedded.

For example, the self-organization materials may be coated on the antireflection film 7a and the hard mask 6a. The self-organization material, for example, can use a block polymer. As the block polymer, a block copolymer (PS-b-PMMA) of polystyrene (PS) and polymethyl methacrylate (PMMA) may be prepared and a number average molecular weight (Mn) of the PS block/the PMMA block may be allowed to be 4,700/24,000. The block copolymer may be phase-separated in one vertical cylinder shape in a guide having a diameter of about 50 nm or more and about 100 nm or less. This maybe molten by a propylene glycol monomethyl ether acetate (PGMEA) solution having a concentration of 1.0 wt %, so that a PGMEA solution of a block copolymer is formed. Then, the PGMEA solution of the block copolymer may be discharged onto the substrate 1 while rotating the substrate 1 at a rotation speed of 1,500 rpm. Then, the substrate 1 may be rotated at a rotation speed of 1,000 rpm for 30 seconds and may be subjected to spin drying so that a block copolymer film can be uniquely formed in the surface. In this way, a block polymer film 11 may be embedded in the hole patterns 7a1 and 6a1, and a block polymer film 12 may be embedded in the hole patterns 7a2 and 6a2.

In some embodiments, before the self-organization materials (e.g., the block copolymers) are coated, a process for controlling contact angles of the surfaces of the guide patterns (e.g., the hole patterns 7a1 and 6a1 and the hole patterns 7a2 and 6a2) may be added. For example, a silane coupling agent may be supplied to the surfaces of the guide patterns to reform lipophilicity, so that lipophilic polystyrene (PS) can be favorably coated in the guide patterns.

In the process illustrated in FIG. 3A, the block polymer film 11 in the hole patterns 7a1 and 6a1 and the block polymer film 12 in the hole patterns 7a2 and 6a2 may be respectively microphase-separated.

For example, the stacked body SLB obtained in the processes up to FIG. 2C may be heated by a heating device, so that the block polymer film 11 and the block polymer film 12 are respectively microphase-separated. When the stacked body SLB is heated on a hot plate at 240° C. for three minutes, the block polymer film 11 and the block polymer film 12 can be microphase-separated.

In the hole patterns 7a1 and 6a1, a self-organization phase, which includes a first polymer portion 11a including a first polymer block chain and a second polymer portion 11b including a second polymer block chain, maybe formed. In this case, in the hole patterns 7a1 and 6a1, a regular pattern (a vertical cylinder shape) may be formed. At the inner surface sides of the hole patterns 7a1 and 6a1, the first polymer portion 11a including the PS may be formed (e.g., segregated), and at the center sides of the hole patterns 7a1 and 6a1, the second polymer portion 11b including the PMMA may be formed.

Similarly, in the hole patterns 7a2 and 6a2, a self-organization phase, which includes a first polymer portion 12a including a first polymer block chain and a second polymer portion 12b including a second polymer block chain, may be formed. In this case, it is possible that in the hole patterns 7a2 and 6a2, a regular pattern is not formed. In the hole patterns 7a2 and 6a2, the first polymer portion 12a including the PS and the second polymer portion 12b including the PMMA may be randomly phase-separated. This is because maximum widths (diameters) of the hole patterns 7a2 and 6a2 deviate from the range of a guide diameter proper for phase separation of the regular pattern (the vertical cylinder shape) of the block copolymer.

In the process illustrated in FIG. 3B, a hole pattern 11c may be developed in the hole patterns 7a1 and 6a1 and a hole pattern 12c may be developed in the hole patterns 7a2 and 6a2.

For example, by the RIE method and the like, the block polymer film 11 and the block polymer film 12 may be etched in an etching condition that etch selectivity of the polymethyl methacrylate (PMMA) with respect to the polystyrene (PS) can be ensured. In this way, in the hole patterns 7a1 and 6a1, the first polymer portion 11a may be allowed to remain and the second polymer portion 11b is selectively removed, so that the hole pattern 11c is formed. In the hole patterns 7a2 and 6a2, the first polymer portion 12a may be allowed to remain and the second polymer portion 12b is selectively removed, so that the hole pattern 12c is formed. The hole pattern 12c may be formed as a dummy pattern.

For example, the hole pattern 11c may have a vertical cylinder shape and a diameter of 25 nm, and may correspond to a hole obtained by contracting the hole patterns 7a1 and 6a1. A part of the surface of the hard mask 5a may be exposed through the hole pattern 11c. The hole pattern 12c may have a random shape. It is possible that the hole pattern 12c does not expose the surface of the hard mask 4.

In order to develop the hole patterns 11c and 12c, it is possible to use another method capable of selectively removing the second polymer portion, instead of the RIE method. For example, a development process or wet etching, in which the hole patterns 11c and 12c are exposed to IPA (isopropyl alcohol) or acetic acid after UV irradiation, may be used.

In the process illustrated in FIG. 3C, in the region R1, the hole pattern 11c may be transferred to the hard mask 5b to form a hole pattern 5b1, and in the region R2, it is possible that the hole pattern 12c (e.g., the dummy pattern) is not transferred.

For example, in the region R1, the hard mask 5a may be etched by the RIE method and the like by using the remaining first polymer portion 11a and the antireflection film 7a as a mask. Apart of the surface of the hard mask 5a exposed through the hole pattern 11c may be selectively removed and the hole pattern 11c is transferred to the hard mask 5b, so that the hole pattern 5b1 is formed. A part of the surface of the hard mask 4 may be exposed through the hole pattern 5b1. In the region R2, since the first polymer portion 12a covers the hard mask 4, it is possible that the hole pattern 12c is not transferred to the hard mask 4.

In the process illustrated in FIG. 4A, the first polymer portion 11a may be removed from the inside of the hole patterns 7a1 and 6a1 of the region R1, and the first polymer portion 12a may be removed from the inside of the hole patterns 7a2 and 6a2 of the region R2.

For example, by the RIE method and the like, the first polymer portion 11a and the first polymer portion 12a may be etched in an etching condition that etch selectivity of the polystyrene (PS) with respect to the hard mask 6a (carbon) can be ensured. In this way, the first polymer portion 11a may be removed from the inside of the hole patterns 7a1 and 6a1 of the region R1, and the first polymer portion 12a may be removed from the inside of the hole patterns 7a2 and 6a2 of the region R2. In the region R2, a part of the surface of the hard mask 4 may be exposed as a bottom surface of the hole patterns 7a2 and 6a2.

In the process illustrated in FIG. 4B, in the region R1, the hole pattern 5b1 may be transferred to the hard mask 4a to form a hole pattern 441, and in the region R2, the hole patterns 7a2 and 6a2 may be transferred to the hard mask 4a to form a hole pattern 4a2.

For example, by the RIE method and the like, the hard mask 4 may be etched. In this case, in the region R1, the hard mask 4a maybe etched using the hard mask 5b as a mask to form the hole pattern 441. Since the hard mask 5b serves as an etching stopper, it is possible to form the hole pattern 441 having a diameter smaller than that of the physical guide (the hole pattern 6a1). In the region R2, the hard mask 4a may be etched using the hard mask 6a as a mask to form the hole pattern 4a2.

In this way, patterns (the hole pattern 441 and the hole pattern 4a2) with different dimensions can be collectively formed in the hard mask 4a. For example, the hole pattern 441 of 25 nm can be formed in the hard mask 4 of the region R1 and the hole pattern 4a2 of 200 nm can be formed in the hard mask 4 of the region R2.

In the process illustrated in FIG. 5A, in the region R1, the hole pattern 441 may be transferred to the hard mask 3a to form a hole pattern 3a1, and in the region R2, the hole pattern 4a2 may be transferred to the hard mask 3a to form a hole pattern 3a2.

For example, by the RIE method and the like, the hard mask 3a may be etched in an etching condition that etch selectivity of the hard mask 3 (e.g., carbon) with respect to the hard mask 4 (e.g., silicon oxide) can be ensured. In this case, in the region R1, the hard mask 3a may be etched using the hard mask 5b and the hard mask 4a as a mask to form the hole pattern 3a1. In the region R2, the hard mask 3a may be etched using the hard mask 4a as a mask to form the hole pattern 3a2.

In this way, patterns (e.g., the hole pattern 3a1 and the hole pattern 3a2) with different dimensions can be collectively formed in the hard mask 3a. For example, the hole pattern 3a1 of 25 nm can be formed in the hard mask 3a of the region R1 and the hole pattern 3a2 of 200 nm can be formed in the hard mask 3a of the region R2.

In the process illustrated in FIG. 5B, in the region R1, the hole pattern 3a1 may be transferred to a processed film 2a to form a hole pattern 2a1, and in the region R2, the hole pattern 3a2 may be transferred to the processed film 2a to form a hole pattern 2a2.

For example, by the RIE method and the like, the processed film 2a may be etched in an etching condition that etch selectivity of the processed film 2a (e.g., silicon oxide) with respect to the hard mask 3a (e.g., carbon) can be ensured. In this case, in the region R1, the processed film 2a may be etched using the hard mask 5b, the hard mask 4a, and the hard mask 3a as a mask to form the hole pattern 2a1. In the region R2, the processed film 2a may be etched using the hard mask 4a and the hard mask 3a as a mask to form the hole pattern 2a2.

In this way, patterns (e.g., the hole pattern 2a1 and the hole pattern 2a2) with different dimensions can be collectively formed in the processed film 2a. For example, the hole pattern 2a1 of 25 nm can be formed in the processed film 2a of the region R1 and the hole pattern 2a2 of 200 nm can be formed in the processed film 2a of the region R2.

As described above, in some embodiments, the pattern formation using the self-organization lithography technology may be performed and a part of the physical guide may be used for the pattern formation as is. In this way, it is possible to reduce the number of processes for forming patterns with different dimensions. That is, it is possible to efficiently form patterns by using the self-organization lithography technology.

Furthermore, in some embodiments, the hard mask 5a maybe selectively formed in the region R1, the hole pattern 11c of the region R1 developed with the self-organization lithography technology may be transferred to the hard mask 5a, and it is possible that the dummy hole pattern 12c of the region R2 is not transferred to a lower layer. In this way, the hole pattern 5b1 of the region R1 and the hole pattern 6a2 (e.g., the physical guide) of the region R2 can be collectively transferred to a lower layer film while using the hard mask 5a as an etching stopper, so that it is possible to reduce the number of processes required for forming patterns with different dimensions.

In some embodiments, instead of forming the dummy hole pattern 12c in the region R2 to prevent the dummy hole pattern 12c from being transferred to a lower layer, the hole pattern 6a2 (the physical guide) of the region R2 maybe covered with a resist pattern, so that a hole pattern by the self-organization lithography technology may be selectively transferred to a lower layer in the region R1.

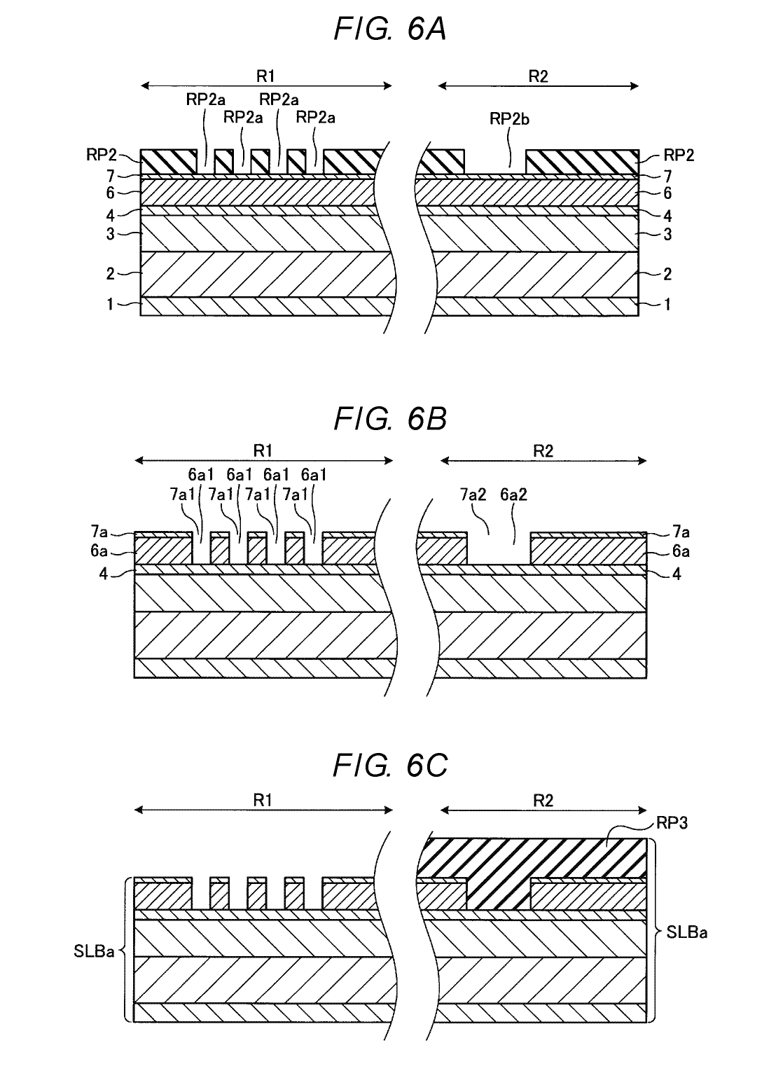

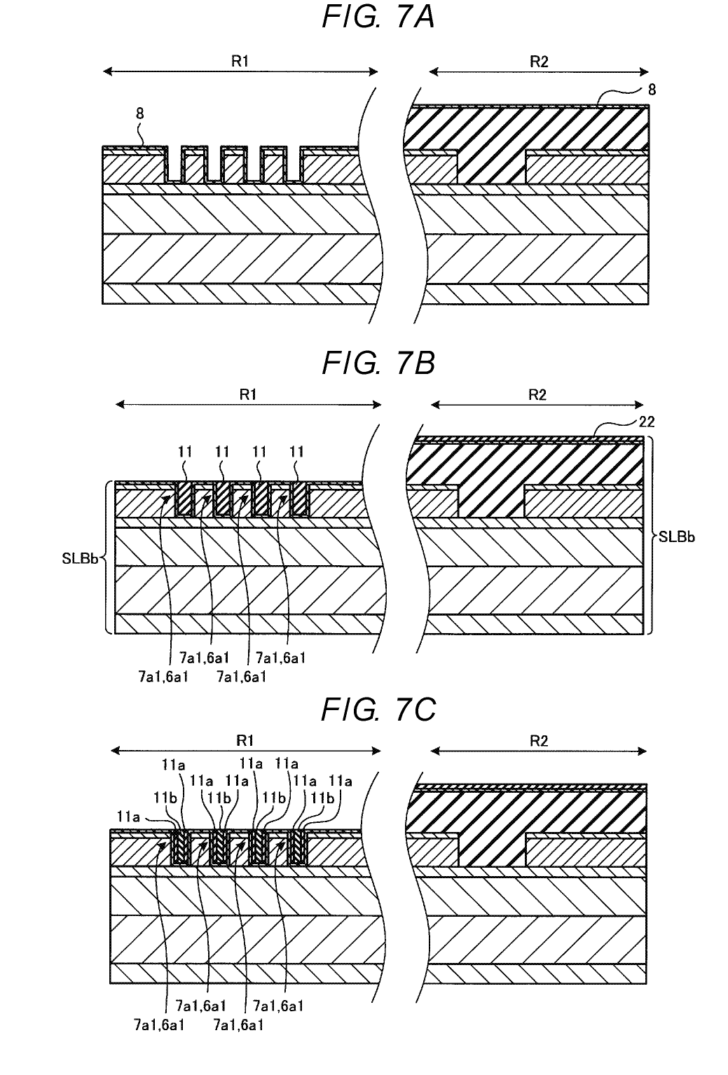

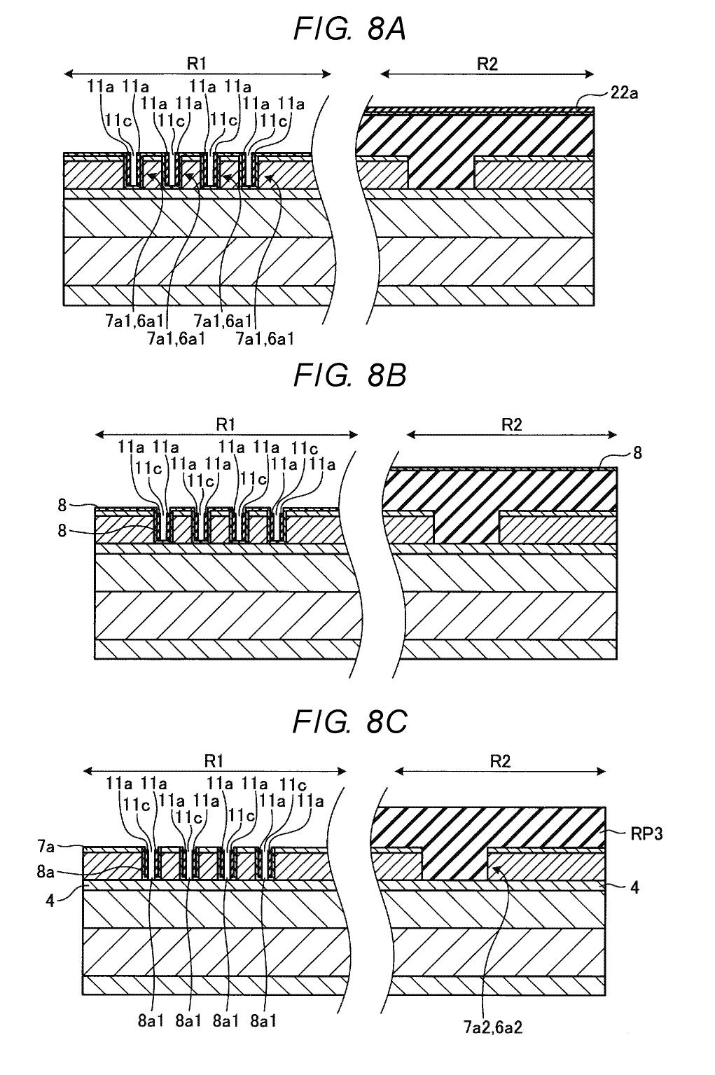

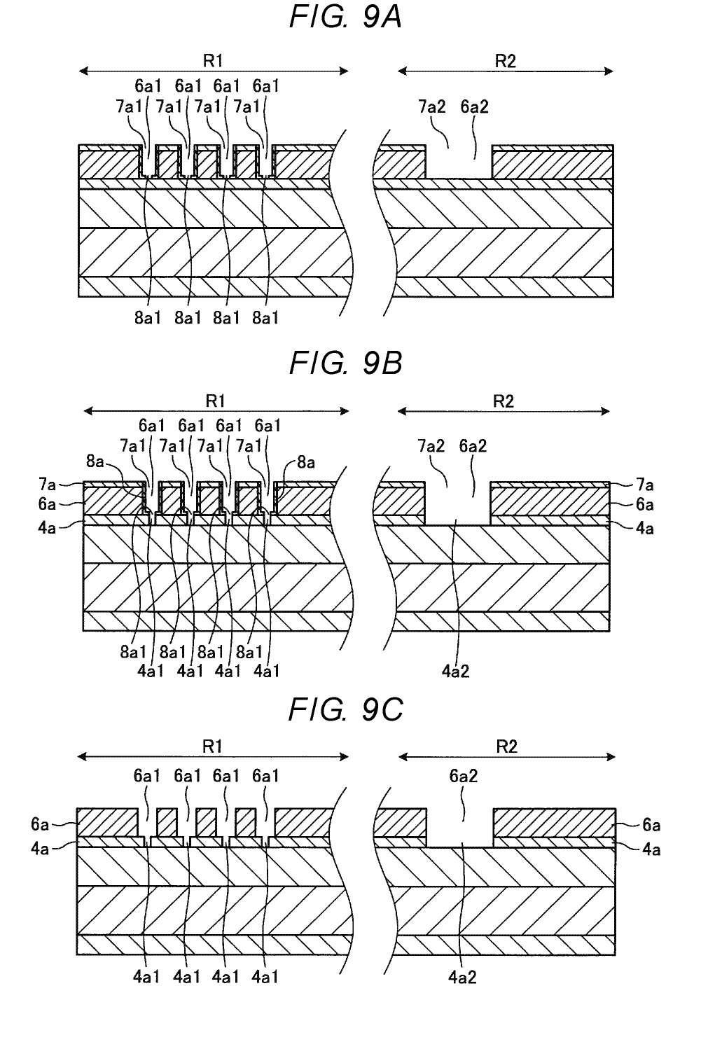

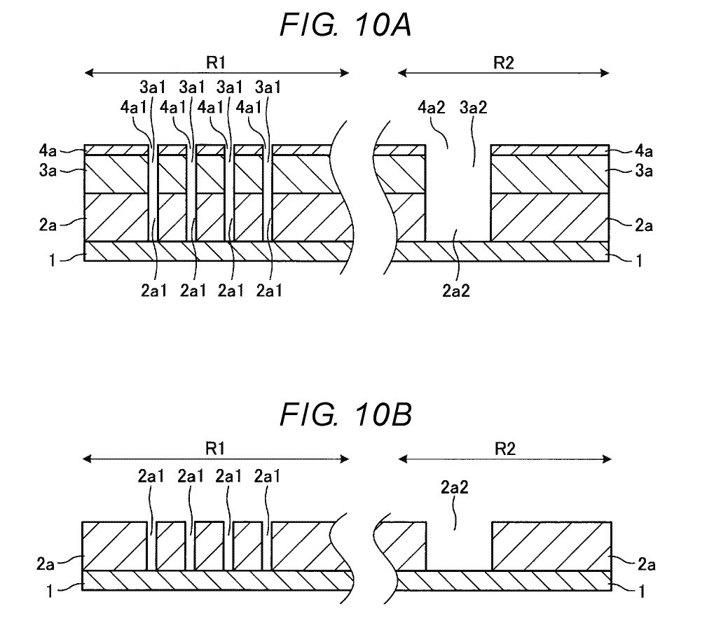

Specifically, as illustrated in FIG. 6A to FIG. 10B, processes different from the embodiment in the following point may be performed. FIG. 6A to FIG. 6C, FIG. 7A to FIG. 7C, FIG. 8A to FIG. 8C, FIG. 9A to FIG. 9C, and FIG. 10A and FIG. 10B are process sectional views illustrating a pattern formation method according to some embodiments.

In the process illustrated in FIG. 6A, the processed film 2, the hard mask 3, the hard mask 4, the hard mask 6, and the antireflection film 7 may be sequentially deposited on the substrate 1, and the resist pattern RP2 similar to that of FIG. 2A may be formed.

In the process illustrated in FIG. 6B, similarly to the process illustrated in FIG. 2B, the hole patterns RP2a and RP2b in the resist pattern RP2 may be transferred to the antireflection film 7a and the hard mask 6a. The formed recess patterns (e.g., the hole patterns 7a1 and 6a1 and the hole patterns 7a2 and 6a2) may serve as physical guides of a self-organization pattern of a subsequent process.

In the process illustrated in FIG. 6C, a resist pattern RP3 for selectively covering the physical guides (e.g., the hole patterns 7a2 and 6a2) of the region R2 may be formed.

In the process illustrated in FIG. 7A, a sidewall spacer film 8 may be formed by the ALD method and the like on the stacked body SLBa obtained in the processes up to FIG. 6C. The sidewall spacer film 8, for example, may be formed with a material in which silicon oxide is a main component. The sidewall spacer film 8 may be formed to cover the inner side surfaces of the hole patterns 7a1 and 6a1 of the region R1 and cover a bottom surface (e.g., a part of the surface of the hard mask 4 exposed through the hole patterns 7a1 and 6a1) of the hole patterns 7a1 and 6a1.

In the process illustrated in FIG. 7B, a self-organization material may be embedded in the physical guides (the hole patterns 7a1 and 6a1) of the region R1. In this case, since the physical guides (the hole patterns 7a2 and 6a2) of the region R2 are covered with the resist pattern RP3, it is possible that the self-organization material is not embedded. That is, the block polymer film 11 may be embedded in the hole patterns 7a1 and 6a1, but it is possible that the block polymer film 11 is not embedded in the hole patterns 7a2 and 6a2. Furthermore, a thin film 22 of a block copolymer may be formed on the sidewall spacer film 8.

In the process illustrated in FIG. 7C, the stacked body SLBb obtained in the processes up to FIG. 7B may be heated by a heating device, so that the block polymer film 11 is microphase-separated. When the stacked body SLBb is heated on a hot plate at 240° C. for three minutes, the block polymer film 11 can be microphase-separated. That is, at the inner surface sides of the hole patterns 7a1 and 6a1, the first polymer portion 11a including the PS is formed (e.g., segregated), and at the center sides of the hole patterns 7a1 and 6a1, the second polymer portion 11b including the PMMA may be formed.

In the process illustrated in FIG. 8A, the hole pattern 11c may be developed in the hole patterns 7a1 and 6a1. For example, by the RIE method and the like, in the hole patterns 7a1 and 6a1, the first polymer portion 11a may be allowed to remain and the second polymer portion 11b may be selectively removed, so that the hole pattern 11c is formed. In this case, a thin film 22a corresponding to the second polymer portion can remain on the sidewall spacer film 8.

In the process illustrated in FIG. 8B, by the RIE method and the like, the thin film 22a of the block copolymer remaining in the region R2 may be removed. In the region R2, the sidewall spacer film 8 may be exposed.

In the process illustrated in FIG. 8C, in the region R1, the hole pattern 11c maybe transferred to a sidewall spacer film 8a to form a hole pattern 8a1.

For example, in the region R1, the sidewall spacer film 8a may be etched using the remaining first polymer portion 11a as a mask by the RIE method and the like. A part of the surface of the sidewall spacer film 8a exposed through the hole pattern 11c may be selectively removed and the hole pattern 11c is transferred to the sidewall spacer film 8a, so that the hole pattern 8a1 is formed. Apart of the surface of the hard mask 4 may be exposed through the hole pattern 8a1. In the region R2, the physical guides (the hole patterns 7a2 and 6a2) may be covered with the resist pattern RP3.

In the process illustrated in FIG. 9A, the first polymer portion 11a may be removed from the inside of the hole patterns 7a1 and 6a1 of the region R1, and the resist pattern RP3 of the region R2 may be removed.

In the process illustrated in FIG. 9B, in the region R1, the hole pattern 8a1 may be transferred to the hard mask 4a to form a hole pattern 441, and in the region R2, the hole patterns 7a2 and 6a2 may be transferred to the hard mask 4a to form a hole pattern 4a2.

In the process illustrated in FIG. 9C, by the RIE method and the like, the sidewall spacer film 8a and the antireflection film 7a may be removed.

In the process illustrated in FIG. 10A, in the region R1, the hole pattern 441 may be transferred to the hard mask 3a to form a hole pattern 3a1, and in the region R2, the hole pattern 4a2 may be transferred to the hard mask 3a to form a hole pattern 3a2. Then, in the region R1, the hole pattern 3a1 may be transferred to the processed film 2a to form a hole pattern 2a1, and in the region R2, the hole pattern 3a2 may be transferred to the processed film 2a to form a hole pattern 2a2.

In the process illustrated in FIG. 10B, by the RIE method and the like, the hard mask 4a and the hard mask 3a may be removed.

In some embodiments, pattern formation using the self-organization lithography technology may be performed and a part of the physical guide may be used for the pattern formation as is. In this way, it is possible to reduce the number of processes required for forming patterns with different dimensions. That is, it is possible to efficiently form patterns by using the self-organization lithography technology.

While certain embodiments have been described, these embodiments have been presented byway of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A pattern formation method comprising:
forming a first pattern in a first film in a first region and forming a second pattern in the first film in a second region by using optical lithography;
forming a third pattern corresponding to the first pattern in a second film below the first film in the first region by using self-organization lithography; and
transferring the third pattern to a third film below the first film and below the second film in the first region and transferring the second pattern to the third film in the second region.

2. The pattern formation method according to claim 1,
wherein the transferring of the third pattern and the transferring of the second pattern are collectively performed by etching using the third pattern and the second pattern as a mask.

3. The pattern formation method according to claim 1, wherein the forming of the third pattern comprises:
embedding a self-organization material in the first pattern and the second pattern and performing microphase separation;
developing a fourth pattern in the first pattern and developing a dummy pattern in the second pattern; and
transferring the fourth pattern to the second film to form the third pattern and without transferring the dummy pattern.

4. The pattern formation method according to claim 1, wherein the forming of the third pattern comprises:
forming a resist pattern for selectively covering the second pattern;
embedding a self-organization material in the first pattern and performing microphase separation;
developing a fourth pattern in the first pattern;
transferring the fourth pattern to the second film to form the third pattern; and
removing the resist pattern.

5. The pattern formation method according to claim 1, wherein a maximum width of the first pattern is smaller than a maximum width of the second pattern, and
a maximum width of the third pattern is smaller than the maximum width of the first pattern.
